(19) United States
(12) Patent Application Publication
(10) Pub. No.: US 2009/0174483 A1
(43) Pub. Date: Jul. 9, 2009

(54) GAIN-CONTROLLED LOW NOISE AMPLIFIER MEANS

(75) Inventors: Leonardus Henricus Maria Hesen, Hegelsom (NL); Edwin Adrianus Johannes Beekmans, Best (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/302,212

(22) PCT Filed: May 15, 2007
(86) PCT No.: PCT/IB2007/051838

§ 371 Date: Nov. 24, 2008

(30) Foreign Application Priority Data
May 24, 2006 (EP) 06114458.0

(51) Int. Cl. H03G 3/00

(52) U.S. Cl. 330/278

(57) ABSTRACT

A gain-controlled low noise amplifier means is provided. The amplifier means comprises an amplifier (T1), a first and second pin diode (D1, D2) coupled in series with opposite forward directions in a negative feedback loop of the amplifier (T1) between an input and an output of the amplifier (T1). The amplifier means furthermore comprises a first current source (I_{C1}) coupled to a node between the first and second pin diode (D1, D2) and a second current source (I_{C2}) coupled to an input of the amplifier (T1).

The present invention relates to a gain-controlled low noise amplifier means and to a video processing device.

Continuous gain-controlled amplifiers are typically used for terrestrial and cable television application. Here, a forward biased pin diode is used as current controlled resistor for a linear continuous gain-controlled trans-impedance amplifier. However, typical low-cost silicon processes do not allow for a monolithic circuit integration. Therefore, a system-in-package SiP may be used to realize a full-integrated solution based on a low-cost silicon process.

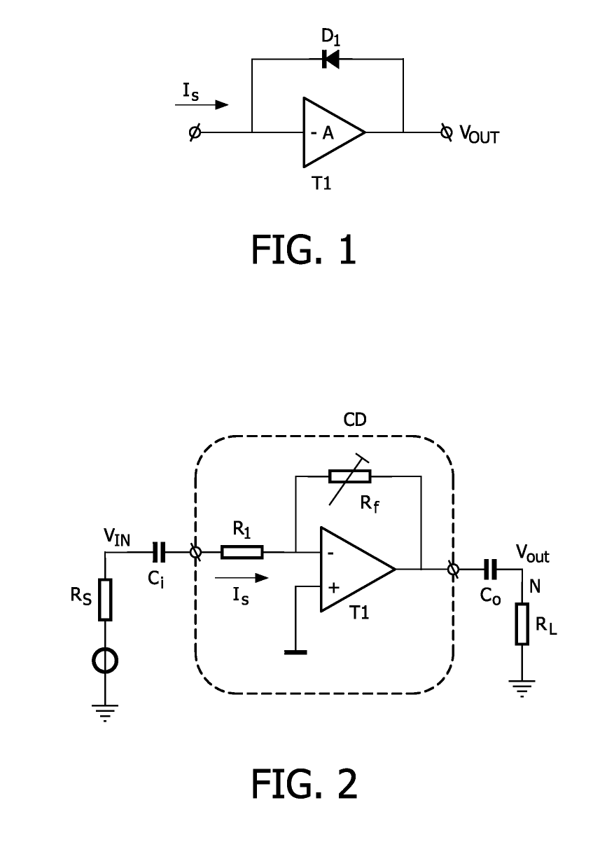

FIG. 1 shows a basic circuit diagram of a trans-impedance amplifier according to the prior art. Here, an amplifier T₁ with open loop gain −A with a pin diode D₁ as current controlled resistor in the feedback loop of the amplifier T₁ is shown.

Amplifiers according to the prior art which use pin diodes for a gain reduction may encounter problems with the linearity performance which may be limited by second and third order distortions. Such limitations may be because of the amplifier or because of a non-linear behavior of the feedback network, e.g. the pin diode as shown in FIG. 1. One way to improve the performance of an amplifier is to increase the power consumption such that a higher voltage headroom and larger bias currents are provided. In addition or alternatively, a full monolithic multi stage amplifier may be used to increase the loop gain. However, a full monolithic wideband splitter amplifier is advantageous because of its low cost, its small size and its minimal power consumption.

In addition, the performance of the pin diode with respect to the linearity must be carefully examined in particular relating to large signal conditions and to low frequencies. A further way to improve the distortions of a pin diode can be the selection of an appropriate pin diode with respect to larger carrier lifetime for improving the performance at low frequency as well as bias conditions. As shown in FIG. 1, the pin diode D₁ is arranged in the feedback loop of the amplifier T₁ to improve its performance with respect to the distortion of the pin diode and the amplifier. This can be achieved as the gain of the circuit is reduced. If large signal conditions are considered, the gain of the circuit may be reduced if the feedback resistance, i.e. the total resistor r_{D} of the pin diode, is lowered. If the feedback resistance comprises a smaller value, the loop gain of the amplifier and the signal handling capabilities of the amplifier may be improved. Furthermore, if the value of the controlled resistance is smaller, a larger control current will be required such that the behavior of the pin diode with respect to the linearity will be improved if required. However, such a linear gain controlled amplifier which does not implement a pre-filtering will encounter some problems if it is used in a variable gain television splitter amplifier. The performance of a single pin diode with respect to the linearity may not be sufficient for low frequency bands. Furthermore, if diodes are connected in series in order to improve a control range as well as the behavior of the pin diode with respect to the linearity, a large voltage level shift in the feedback loop may result in some problems, in particular if the amplifier is implemented in a low voltage design. This problem may be solved by using an AC-coupled parallel feedback circuit to prevent any unwanted voltage shifts. However, such a solution would need a very large decoupling capacitor with a value typically of greater than 100 pF, in particular for low frequency television bands.

FIG. 2 shows a circuit diagram of a highly linear gain-controlled amplifier according to the prior art. On a chip die CD, a first resistor R1 and a second resistor Rf as well as an amplifier T₁ is provided. At the input of the chip die CD, an input capacitor Ci and a source resistor Rs is provided. At the output, an output capacitor Co and a load resistor R_{L} is provided. The amplifier shown in FIG. 2 constitutes a highly linear gain-controlled low noise amplifier. This amplifier is based on a negative feedback with the second resistor R_{F} arranged in the feedback loop allowing the signal splitting at the low-ohmic output (e.g. splitter amplifier). Such an amplifier will have a high linearity and will enable a low noise operation as the gain is controlled by switching the resistor Rf in discrete steps.

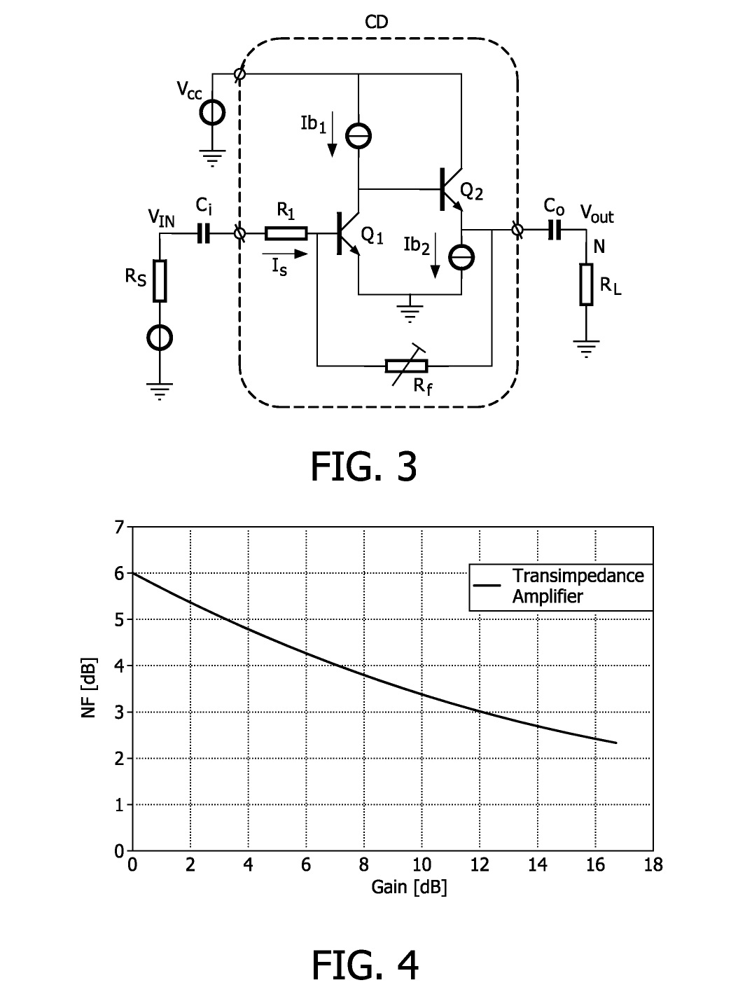

FIG. 3 shows a circuit diagram of the circuit according to FIG. 2. Here, the amplifier is shown in more detail. In particular, a two-stage negative feedback amplifier is depicted in FIG. 3. The amplifier will comprise a first and second transistor Q1, Q2 as well as a first and second current source Ib₁, Ib₂ to implement the two stages.

FIG. 4 shows a graph of a NF versus gain relation of an amplifier according to FIG. 2. The Voltage Standing Wave Ratio is 3, the amplifier T₁ is noiseless and Gain=2Vₒᵤₜ/Vₛ. By using the trans-impedance amplifier as shown in FIG. 2 a high gain is required to improve the performance. By increasing the gain the amplifier NF decreases and the overall system NF will also improve significant. The higher gain will improve the noise figure but require continuous variable gain during operation to prevent signal overload.

A (silicon) tuner for analog and digital TV reception (e.g. TV, DVD-R and PC) require a low NF with high linearity.

U.S. Pat. No. 6,265,942 B1 shows a gain-controlled amplifier with a high dynamic range for frequencies in the GHz range, wherein the amplifier comprises an adaptive controlled feedback network with a plurality of series connected PIN diodes. However, the amplifier requires n-times Vₚᵢₙ (n PIN diodes connected in series with the same forward direction) to improve the linearity of the amplifier such that this amplifier is not suited for a low voltage application.

It is therefore an object of the invention to provide a linear gain-controlled amplifier which has an improved linearity behavior.

This object is solved by an amplifier means according to claim 1 and a video processing device according to claim 7.

Therefore, a gain-controlled low noise amplifier means is provided. The amplifier means comprises an amplifier unit, a first and second pin diode coupled in series with opposite forward directions in a negative feedback loop of the amplifier unit between an input and an output of the amplifier unit. The amplifier means furthermore comprises a first current source coupled to a node between the first and second pin diode and a second current source coupled to an input of the amplifier unit.

According to an aspect of the invention, the first and second pin diode are coupled together in a common anode configuration. Alternatively, the first and second pin diode are coupled together in a common cathode configuration.

According to a further aspect of the invention, the amplifier means comprises a chip die on which the amplifier and the first and second current source are arranged.

According to still a further aspect of the invention, the amplifier means comprises a system-in-packet arrangement with a chip die and the first and second pin diode.

According to still a further aspect of the invention, the amplifier means comprises a high pass filter coupled to the second source for filtering the noise from the second current source.

The invention also relates to a video processing device with a gain-controlled low noise amplifier means. The amplifier means comprises an amplifier unit, a first and second pin diode coupled in series with opposite forward directions in a negative feedback loop of the amplifier unit between an input and an output of the amplifier unit. The amplifier means furthermore comprises a first current source coupled to a node between the first and second pin diode and a second current source coupled to an input of the amplifier unit.

The invention relates to the idea to improve the linearity of an amplifier by coupling two pin diodes in a back-to-back configuration or in a common anode configuration in a negative feedback loop of the amplifier. Any second order distortions of the individual diodes will be cancelled if the two pin diodes are equally biased. Any third order distortions and a gain range may be improved without a voltage drop across the feedback network. The amplifier according to the invention will allow a DC-coupled feedback network without the need for decoupling capacitors. Furthermore, a voltage drop across the feedback network is avoided such that the amplifier may be implemented in a low voltage solution or in a solution with a higher voltage headroom.

The forward bias current or the control current for the pin diodes may be integrated fully and may be implemented by only two current sources. A main control current will be equally split into two currents. The bias current through a second pin diode is the same as the bias current through a first pin diode. As these two bias currents are equal, any second order distortions can be cancelled. The control current at the amplifier output can be absorbed by internal biasing within the amplifier circuitry. Therefore, no additional circuitry is required.

The embodiments and advantageous of the present invention will now be described in more detail with reference to the drawings.

FIG. 1 shows a basic circuit diagram of a trans-impedance amplifier according to the prior art;

FIG. 2 shows a circuit diagram of a highly linear gain-controlled amplifier according to the prior art;

FIG. 3 shows a circuit diagram of the circuit according to FIG. 2;

FIG. 4 shows a graph of a NF versus gain relation of an amplifier according to FIG. 3;

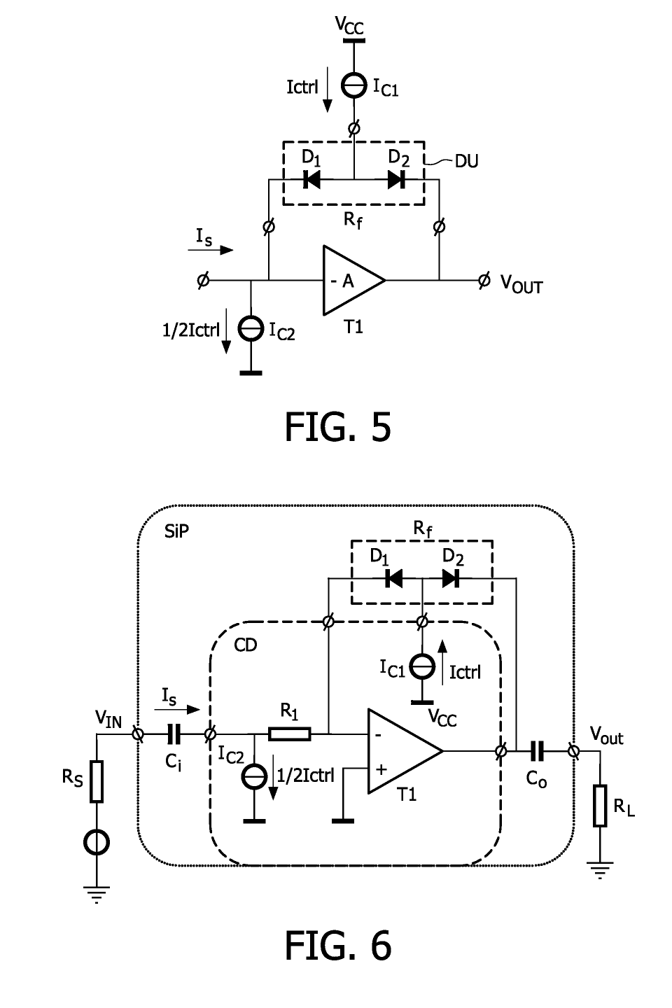

FIG. 5 shows a circuit diagram of a linear gain-controlled amplifier according to a first embodiment;

FIG. 6 shows a circuit diagram of a linear gain-controlled amplifier according to a second embodiment;

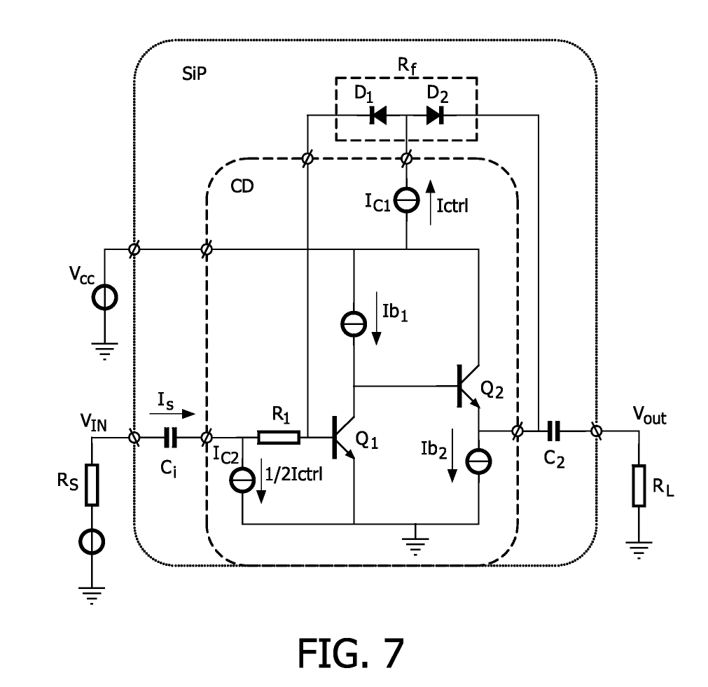

FIG. 7 shows a circuit diagram of an amplifier corresponding to the circuit diagram of FIG. 6 in more detail according to a third embodiment;

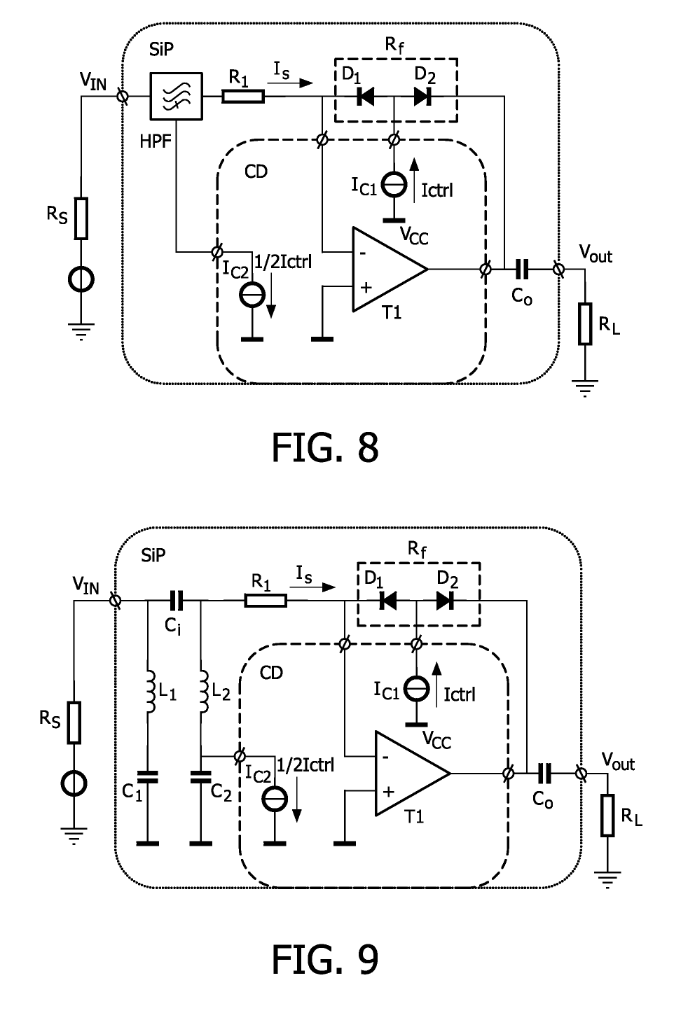

FIG. 8 shows a circuit diagram of an amplifier according to a fourth embodiment;

FIG. 9 shows a circuit diagram of the amplifier according to FIG. 8 in more detail according to a fifth embodiment;

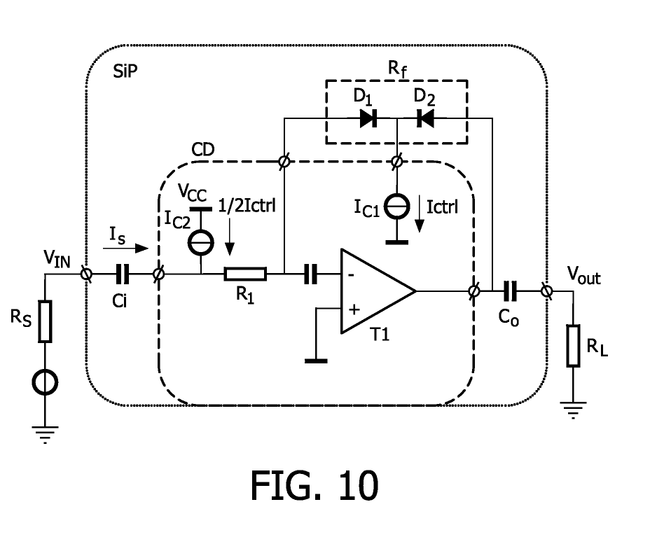

FIG. 10 shows a circuit diagram of an amplifier according to a sixth embodiment; and

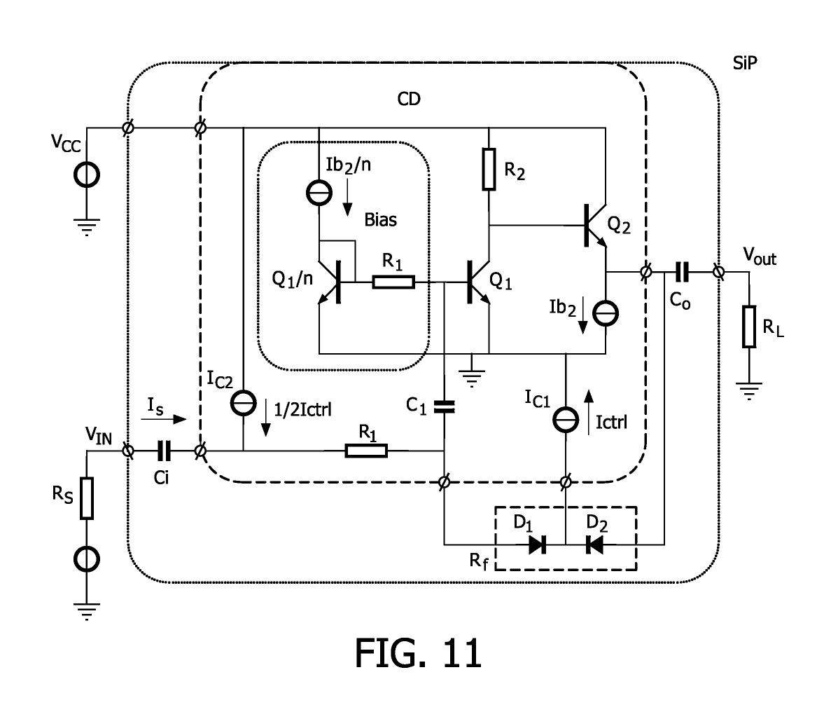

FIG. 11 shows a circuit diagram of the amplifier according to FIG. 10 in more detail according to a seventh embodiment.

FIG. 5 shows a circuit diagram of a linear gain-controlled amplifier according to a first embodiment. In particular, the amplifier is implemented as a highly linear gain-controlled trans-impedance amplifier. In a feedback path of the amplifier T₁, a diode unit DU (implementing the current controlled resistor R_{F}) is provided which consists of a first and second pin diode D1, D2 which are preferably coupled back-to-back. A first current source I_{C1} is coupled to a node BB which corresponds to the back-to-back node to which the pin diodes are coupled. A second current source I_{C2} is coupled at the input of the amplifier T₁. The first current source relates to the control current I_{CTRL}. The second current source IC2 will provide a current of 0,5 I_{CTRL}.

FIG. 6 shows a circuit diagram of a linear gain-controlled amplifier according to a second embodiment. The basic structure of the amplifier according to the second embodiment corresponds to the structure of the amplifier according to FIG. 2 because of its functionality proven already in previous version of silicon tuners. The amplifier according the second embodiment relates to a combination of the circuits according to FIGS. 3 and 5. In the negative feedback loop of the amplifier T₁, a (current controlled) resistor R_{F} is implemented by two pin diodes D1, D2 coupled back-to-back (or in common anode) pin diodes. A first current source I_{C1} is coupled to a node BB which corresponds to the back-to-back node to which the pin diodes D1, D2 are coupled. A second current source I_{C2} is coupled at the input of the amplifier T₁. The first current source relates to the control current I_{CTRL}. The second current source IC2 will provide a current of 0,5 I_{CTRL}. The first and second current source IC1, IC2, the amplifier T₁ and the first resistor R1 are implemented on the chip die CD. At the input of the chip die CD, an input capacitor Ci and a source resistor Rs and at the output, an output capacitor Co and a load resistor R_{L} is provided. The chip die CD, the pin diodes D1, D2, the input capacitor Ci and the output capacitor Co are implemented as a system-in-package SiP.

By placing the diodes D1, D2 back-to-back the second order distortion of the individual diodes will be cancelled. A common cathode configuration is also possible but require a higher DC voltage level at the input and output or a negative supply voltage. The feedback configuration will also improve the third order distortion and the range of the feedback resistance. The two back-to-back diodes D1, D2 need to be matched and can be ordered as standard discrete SMD component with comparable cost as a single pin-diode. The special arrangement of the diodes avoids voltage drop across the feedback network and allows a DC-coupled feedback network. In addition, no decoupling capacitors are required and the configuration simplifies a low voltage solution or reserve more voltage headroom within the negative feedback amplifier.

The forward bias current or control current for the pin diodes can fully be integrated and can simply be implemented with only two current sources I_{C1} & I_{C2}. The main control current I_{C1} is placed at node BB, i.e. the common anode and will be split equally in two bias currents because of the connection of current source I_{C2} (I_{C2}=½I_{C1}). The second current source I_{C2} can be placed before or after the input resistor. However, the implementation according to FIG. 6 is preferred for loop gain and noise advantages. The bias current through the second pin diode D₂ corresponds to the bias current through D₁ to cancel any second order distortion. The current through the second diode D₂ will flow towards the output of the amplifier.

FIG. 7 shows a circuit diagram of an amplifier corresponding to the circuit diagram of FIG. 6 in more detail according to a third embodiment. According to the third embodiment the amplifier T₁ is implemented as a simplified two-stage negative feedback amplifier, i.e. the circuit according to the third embodiment corresponds to a combination of the circuits of FIG. 6 and FIG. 3. The amplifier T₁ comprise a first and second transistor Q1, Q2 as well as a third and fourth current source Ib₁, Ib₂ to implement the two stages.

At the input of the amplifier T₁ the common emitter transistor Q₁ (or common source in case of a FET) is used to minimize the NF and maximize the loop gain. At the output of the amplifier T₁ a common collector or emitter-follower (or source follower in case of a FET) is used to realize very low-ohmic output impedance. The bias current Ib₂ of the third current source relating to the output stage will sink the bias current from the second pin diode D2. The current in the output stage Q₂ decreases because of the control current Ictrl, however this may be neglected or compensated by implementing Ib2 as a function of Ictrl when required. The base current of the first stage Q1 can be compensated by the current from the second current source I_{C2} to cancel any second order distortions.

E.g. in a TV splitter configuration the bias current in the output stage Ib2 is at least a 10 times larger then Ictrl under normal operation, i.e. so less influence can be expected.

The actual noise influence from the first and second current source I_{C1} and I_{C2} depend on the control current Ictrl. The bias current through the diodes D1, D2 is minimal for low noise or high gain operation. This minimizes the shot-noise when it is most critical and allows maximum voltage headroom for degeneration within the current source. The impact on the noise figure is approx. 0.2 dB and is mainly shot-noise from I_{C2}.

FIG. 8 shows a circuit diagram of an amplifier according to a fourth embodiment. The circuit diagram according to the fourth embodiment is based on the circuit diagram according to the second embodiment of FIG. 6. In addition to the circuit elements of FIG. 6 a high-pass filter HPF is provided at the input of the amplifier for filtering the bias current I_{C2} such that the shot-noise from the bias current can be filtered without extra components if the filter which is required for CENELEC is used. The high-pass filter HPF can e.g. be implemented as a Citizen-Band filter.

FIG. 9 shows a circuit diagram of the amplifier according to FIG. 8 in more detail according to a fifth embodiment. In FIG. 9 the CB-filter HPF is implemented with two notches. The noise from the current source I_{C2} is filtered via a low-pass filter formed by a second inductance L₂ and a second capacitor C₂. The resistor R₁ may be arranged on the chip-die if required but by placing it in the module instead a more accurate input match (optimized for noise) can be realized and one die bonding can be avoided.

FIG. 10 shows a circuit diagram of an amplifier according to a sixth embodiment. The circuit diagram according to the sixth embodiment is based on the circuit diagram according to the second embodiment of FIG. 6. However, while the two pin diodes D1, D2 are coupled back-to-back according to FIG. 6, the two pin diodes D1, D2 are implemented with a common cathode. Accordingly, the DC voltage at the pin diodes D1, D2 are increased to maximize the voltage swing at the output of the amplifier. Increasing the DC voltage improves the linearity performance of the output current source. With a higher DC voltage a common cathode configuration with a grounded current source I_{C1} becomes feasible. With the same two-stage negative feedback amplifier (grounded Common Emitter input stage and Common Collector output stage) an AC coupling at the input is needed (Ube≈0.8V). Therefore, the amplifier is less noise sensitive as a larger voltage headroom is available for I_{C2}. The current source for I_{C1} can be implemented a NPN type. The current I_{C2} does not need a base current, i.e. so no additional compensation is required for I_{C2.}

FIG. 11 shows a circuit diagram of an amplifier according to a seventh embodiment. The circuit diagram according to the seventh embodiment corresponds to the circuit diagram of FIG. 10, wherein the amplifier is shown in more detail. Because of the AC coupling at the input of the amplifier, a different bias schema for the input stage is required as there is now no DC loop.

An additional integrated resistor may be coupled with the pin diodes in serial and or parallel connection. This will decrease the gain range but can improve the distortion. Passive serial resistors also improve the stability of the amplifier and damp unwanted oscillations from the bond wires and other parasitic components.

The amplifiers according to the invention can be used in the 4^{th} generation silicon tuners for realizing a full performance single chip silicon front end for analog and digital TV's, DVD-R and PC's (incl. laptops). Furthermore, the amplifiers according to the invention may be implemented in other wideband AGC amplifiers that have very high linearity requirements.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

Furthermore, any reference signs in the claims shall not be construed as limiting the scope of the claims.

1. Gain-controlled low noise amplifier means, comprising:
an amplifier unit;
a first and second pin diode coupled in series with opposite forward directions in a negative feedback loop of the amplifier unit between an output and an input of the amplifier;
a first current source coupled to a node between the first and second pin diode; and
a second current source coupled to an input of the amplifier unit.

2. Amplifier means according to claim 1, wherein the first and second pin diode are coupled together in a common anode configuration.

3. Amplifier means according to claim 1, wherein the first and second pin diode are coupled together in a common cathode configuration.

4. Amplifier means according to claim 2, further comprising a chip die, wherein the amplifier unit, and the first and second current source are arranged on the chip die.

5. Amplifier means according to claim 4, further comprising a system-in-package arrangement having the chip die and the first and second pin diode.

6. Amplifier means according to claim 4, further comprising a high pass filter coupled to the second current source for filtering the noise from the second current source.

7. Video processing device comprising a gain-controlled low noise amplifier means, comprising:
an amplifier unit,
a first and second pin diode coupled in series with opposite forward directions in a negative feedback loop of the amplifier unit between an output and an input of the amplifier;
a first current source coupled to a node between the first and second pin diode; and
a second current source coupled to an input of the amplifier unit.

8. Data processing apparatus comprising a gain-controlled low noise amplifier means according to claim 1.
